(19) United States
(12) Patent Application Publication
(10) Pub. No.: US 2026/0256026 A1
(43) Pub. Date: Aug. 27, 2026

(54) OPTICAL PACKAGE STRUCTURE AND MANUFACTURING METHOD THEREOF

(71) Applicant: SILICONWARE PRECISION INDUSTRIES CO., LTD., Taichung City (TW)

(72) Inventors: Chia-Pu LIANG, Taichung City (TW); Chia-Hsi HSIEH, Taichung City (TW); Pei-Hsuan KE, Taichung City (TW); Jun-Yan LI, Taichung City (TW)

(73) Assignee: SILICONWARE PRECISION INDUSTRIES CO., LTD., Taichung City (TW)

(21) Appl. No.: 19/364,228

(22) Filed: Oct. 21, 2025

(30) Foreign Application Priority Data
Feb. 27, 2025 (TW) 114107401

(51) Int. Cl. H01L 25/18; G02B 6/42; G02B 6/43; H01L 23/00; H01L 23/538

(52) U.S. Cl. CPC H10W 90/00; G02B 6/4206; G02B 6/4214; G02B 6/4239; G02B 6/43; H10W 70/614; H10W 90/297; H10W 90/792

(57) ABSTRACT

An optical package structure and a manufacturing method thereof are provided, in which an electronic component is disposed in a groove of a circuit board, a semiconductor component is stacked on the electronic component, and an optical component is disposed on and connected to the semiconductor component. The electronic component is formed with a plurality of first conductive vias, and the semiconductor component and the optical component are electrically connected to the circuit board through the plurality of first conductive vias, thereby reducing electrical transmission paths.

### BACKGROUND

### 1. Technical Field

The present disclosure relates to a semiconductor package structure, and more particularly, to an optical package structure with an optical component and a manufacturing method thereof.

### 2. Description of Related Art

With the vigorous development of the electronics industry, electronic products are gradually moving towards multi-functionality and high performance. The current fifth-generation (5G) communication technology has been applied to various fields such as Internet of Things (IoT), Industrial Internet of Things (IIoT), cloud, artificial intelligence (AI), autonomous cars, and medical care. With the expansion of the application level, a very large amount of data is generated that needs to be efficiently transmitted, computed, and stored. In particular, there is a huge demand for data transmission. Therefore, the industry has begun to use “light” instead of “electricity” as the carrier of data transmission to increase the transmission capacity, efficiency, and distance, and to reduce energy consumption during the transmission process. In this context, co-packaged optical devices have become the development trend of future semiconductor and packaging technology.

FIG. 1 is a schematic cross-sectional view of a conventional co-packaged optical device 1, in which an optoelectronic module 11 is disposed on a circuit board 10, and the optoelectronic module 11 includes a semiconductor chip 112 formed in a package structure 111 and an optical chip 113 disposed on and connected to the package structure 111, wherein a side end of the optical chip 113 is connected to an optical fiber 14, and a shelf 15 is disposed underneath the junction between the optical chip 113 and the optical fiber 14, so that optical signals can be transmitted to the optoelectronic module 11 for communication. At the same time, a switch chip 12 (e.g., a switched integrated circuit or switched IC) needs to be additionally disposed on and connected to the circuit board 10 so that the co-packaged optical device 1 can be used in an end product, wherein the switch chip 12 is first disposed on a substrate 13, and then is disposed on and connected to the circuit board 10 via the substrate 13.

However, the optical chip 113 and the switch chip 12 in the co-packaged optical device 1 need to transmit signals via the circuitries within the circuit board 10 and the substrate 13. Not only is the overall size and thickness of the co-packaged optical device 1 excessively large, which is unfavorable for the miniaturization of electronic products, but the excessively long signal transmission path in the co-packaged optical device 1 can also easily cause signal loss, resulting in issues in end-product applications. Additionally, there is the risk of the shelf 15 being suspended, leading to insufficient support for the optical fiber 14 and the potential for breakage.

Therefore, how to overcome the aforementioned problems of the prior art has become an urgent issue to be solved.

### SUMMARY

In view of the aforementioned shortcomings of the prior art, the present disclosure provides an optical package structure, which comprises: a circuit board having a first side, a second side opposite to the first side, and a groove formed on the first side; an electronic component having a first surface, a second surface opposite to the first surface, and a plurality of first conductive vias penetrating through the first surface and the second surface, wherein the electronic component is accommodated in the groove via the second surface and is electrically connected to the circuit board; a semiconductor component having a third surface and a fourth surface opposite to the third surface, wherein the semiconductor component is disposed on the electronic component via the fourth surface and is electrically connected to the electronic component; and an optical component disposed on and electrically connected to the semiconductor component.

The present disclosure further provides a method of manufacturing an optical package structure, and the method comprises: providing a circuit board having a first side, a second side opposite to the first side, and a groove formed on the first side; disposing an electronic component in the groove of the circuit board, wherein the electronic component has a first surface, a second surface opposite to the first surface, and a plurality of first conductive vias penetrating through the first surface and the second surface, wherein the electronic component is accommodated in the groove via the second surface and is electrically connected to the circuit board; disposing a semiconductor component on the electronic component, wherein the semiconductor component has a third surface and a fourth surface opposite to the third surface, wherein the semiconductor component is disposed on the electronic component via the fourth surface and is electrically connected to the electronic component; and disposing an optical component on the semiconductor component, wherein the optical component is electrically connected to the semiconductor component.

In the aforementioned optical package structure and method, the electronic component is a switched application-specific integrated circuit.

In the aforementioned optical package structure and method, the semiconductor component is an electronic integrated circuit component.

In the aforementioned optical package structure and method, the semiconductor component is formed with a plurality of second conductive vias penetrating through the third surface and the fourth surface.

In the aforementioned optical package structure and method, the semiconductor component is disposed on the circuit board and the electronic component via the fourth surface and is electrically connected to the circuit board and the electronic component.

In the aforementioned optical package structure and method, the optical component is an optical chip or an optical module.

In the aforementioned optical package structure and method, the optical module comprises a coupler, an optical chip, a total reflection mirror, and an optical fiber array unit.

In the aforementioned optical package structure and method, the optical component is provided with an optical accessory, and the optical accessory is supported by the circuit board.

In the aforementioned optical package structure and method, the present disclosure further comprises: forming a filling layer between the optical component and the circuit board to cover the semiconductor component and the electronic component.

In the aforementioned optical package structure and method, the present disclosure further comprises: placing a plurality of conductive components on the second side of the circuit board.

In the aforementioned optical package structure and method, the circuit board, the electronic component disposed in the groove of the circuit board, the semiconductor component, and the optical component constitute a three-layer vertical stacked structure.

It can be seen from the above that, in the optical package structure and the manufacturing method thereof of the present disclosure, the electronic component formed with a plurality of first conductive vias is accommodated in the groove of the circuit board so that the overall size of the optical package structure is reduced. Then, the semiconductor component is stacked on the electronic component, and the optical component is stacked on the semiconductor component, thereby constituting the three-layer vertically stacked optical package structure. At the same time, the optical component, the semiconductor component, the electronic component, and the circuit board can be electrically connected to each other directly through the plurality of first conductive vias formed in the electronic component and the plurality of second conductive vias formed in the semiconductor component. As a result, the signal transmission paths between the optical component, the semiconductor component, the electronic component, and the circuit board are reduced, thereby improving the transmission speed. Furthermore, the optical accessory can be supported by the circuit board to reduce the risk of breakage of the optical component.

### BRIEF DESCRIPTION OF THE DRAWINGS

FIG. 1 is a schematic cross-sectional view showing a conventional co-packaged optical device.

FIG. 2A to FIG. 2E are schematic cross-sectional views illustrating a method of manufacturing an optical package structure according to the present disclosure.

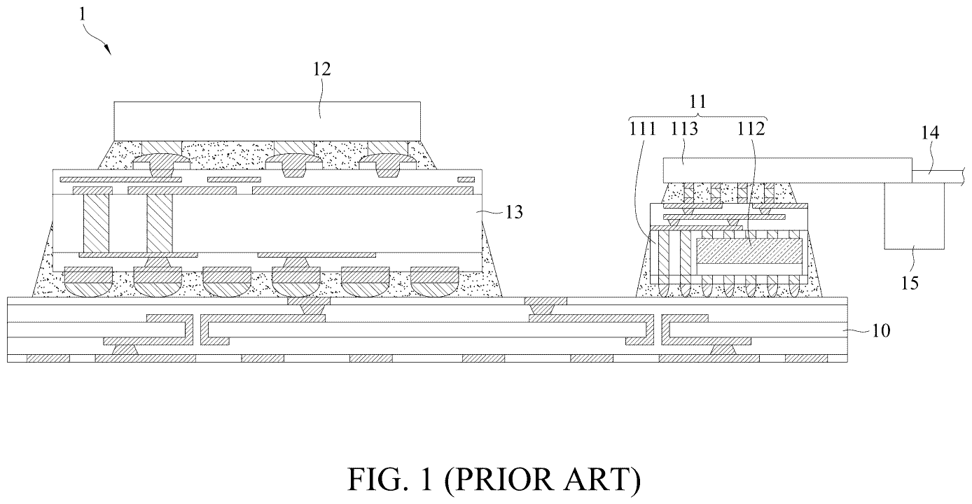

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “underneath,” “first,” “second,” “third,” “fourth,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

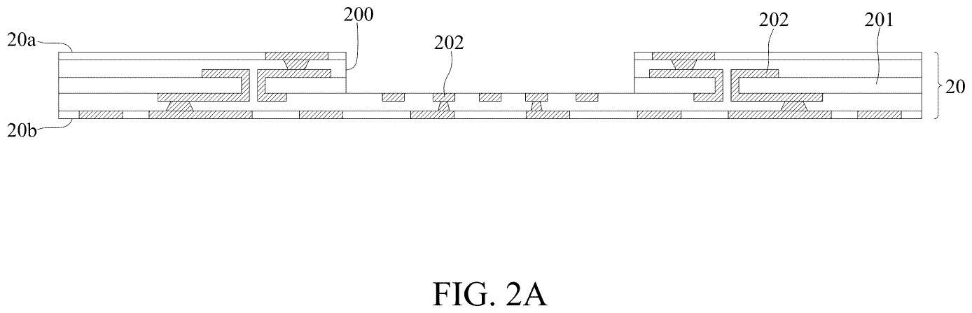

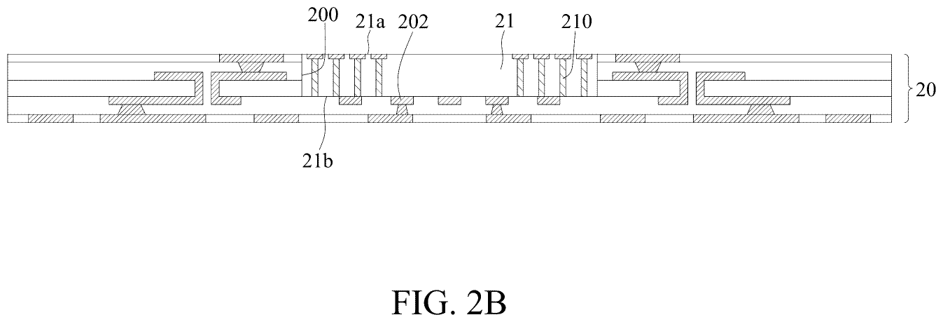

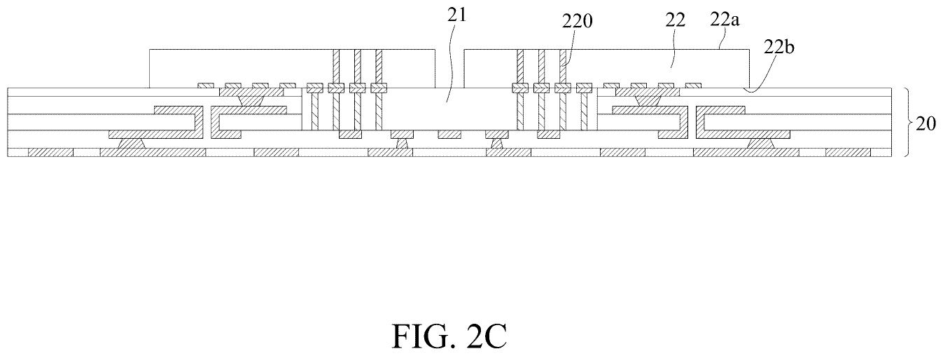

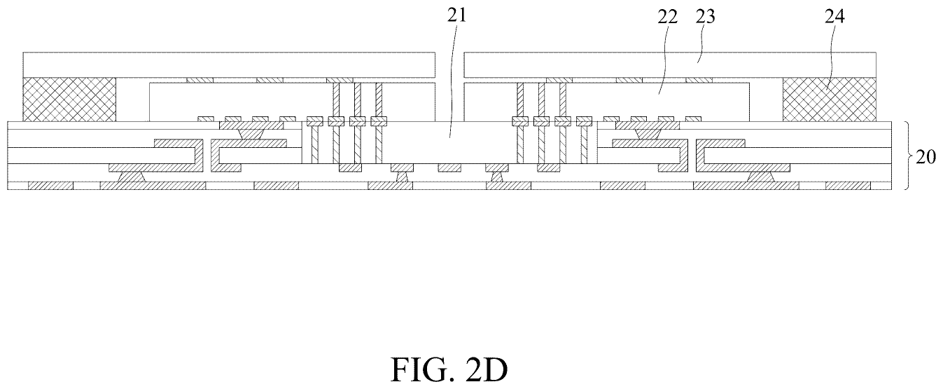

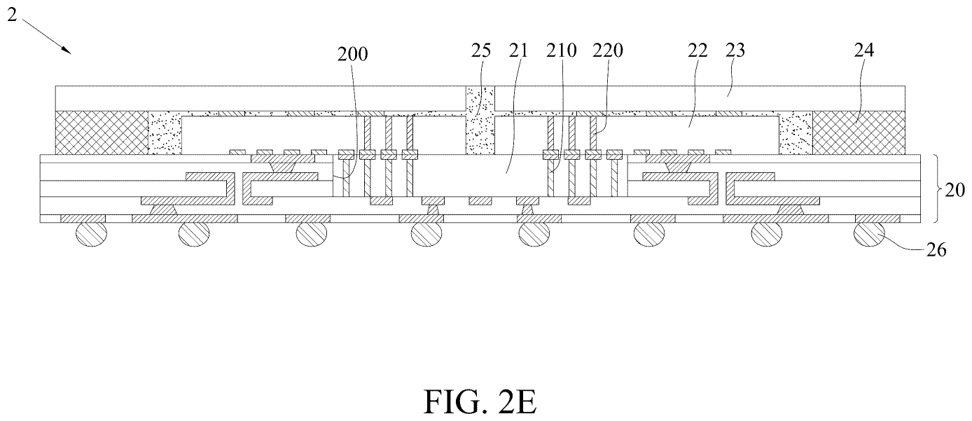

FIG. 2A to FIG. 2E are schematic cross-sectional views illustrating a method of manufacturing an optical package structure 2 according to the present disclosure.

As shown in FIG. 2A, a circuit board 20 is provided, and at least one groove 200 is formed in the circuit board 20.

In one embodiment, the circuit board 20 has a first side 20a and a second side 20b opposite to the first side 20a. The circuit board 20 includes at least one insulating layer 201 and at least one circuit layer 202 bonded to the insulating layer 201. The insulating layer 201 is made of polybenzoxazole (PBO), polyimide (PI), prepreg (PP), or other dielectric materials. The circuit layer 202 is, for example, a fan-out redistribution layer. The circuit layer 202 is made of, for example, copper metal.

The groove 200 can be formed on the first side 20a by methods such as laser cutting or tool cutting, and a portion of the circuit layer 202 is exposed from the bottom of the groove 200. The groove 200 can also be formed via a circuit layer build-up process of a circuit board without using the aforementioned cutting methods.

As shown in FIG. 2B, an electronic component 21 is disposed in the groove 200 and is electrically connected to the circuit board 20.

In one embodiment, the electronic component 21 is, for example, a switched application-specific integrated circuit (switched ASIC). The electronic component 21 has a first surface 21a and a second surface 21b opposite to the first surface 21a. A plurality of first conductive vias 210 (e.g., conductive through-silicon vias) penetrating through the first surface 21a and the second surface 21b are formed in the electronic component 21. The electronic component 21 is electrically connected to the circuit layer 202 at the bottom of the groove 200 of the circuit board 20 via the second surface 21b (via conductive components such as solder bumps or copper bumps).

As shown in FIG. 2C, at least one semiconductor component 22 (two semiconductor components 22 are shown in FIG. 2C) is disposed on the circuit board 20 and the electronic component 21, and the semiconductor component 22 is electrically connected to the circuit board 20 and the electronic component 21.

In one embodiment, the semiconductor component 22 is, for example, an electronic integrated circuit (EIC) component. The semiconductor component 22 has a third surface 22a and a fourth surface 22b opposite to the third surface 22a. A plurality of second conductive vias 220 penetrating through the third surface 22a and the fourth surface 22b are formed in the semiconductor component 22. The semiconductor component 22 is electrically connected to the circuit board 20 and the electronic component 21 via the fourth surface 22b (via conductive components such as solder bumps or copper bumps).

As shown in FIG. 2D, an optical component 23 is disposed on the semiconductor component 22, and the optical component 23 is electrically connected to the semiconductor component 22 (via conductive components such as solder bumps or copper bumps). Furthermore, an optical accessory 24 (such as an optical fiber slot/socket, a lens, or a bracket/shelf, etc.) is disposed underneath the optical component 23, wherein the optical accessory 24 can be supported by the circuit board 20 to reduce the risk of breakage of the optical component 23 and/or the optical accessory 24.

The optical component 23 is, for example, an optical chip or an optical module (a photonic integrated circuit [PIC] module), wherein the optical module comprises at least one coupler, at least one optical chip, at least one total reflection mirror, at least one optical fiber array unit (FAU), etc.

As shown in FIG. 2E, a filling layer 25 is formed between the optical component 23 and the circuit board 20, such that the filling layer 25 encapsulates the semiconductor component 22 and the electronic component 21, and a plurality of conductive components 26 (such as solder bumps or copper bumps) can be placed on the second side 20b of the circuit board 20. As a result, the optical package structure 2 of the present disclosure is obtained. Subsequently, the optical package structure 2 can be electrically connected to an external device via the plurality of conductive components 26.

Via the aforementioned manufacturing method, the present disclosure further provides an optical package structure 2, which comprises: a circuit board 20 having a groove 200, an electronic component 21 disposed in the groove 200 of the circuit board 20, a semiconductor component 22 stacked on the circuit board 20 and the electronic component 21, and an optical component 23 stacked on the semiconductor component 22.

The circuit board 20 has a first side 20a and a second side 20b opposite to the first side 20a, and the groove 200 is formed on the first side 20a.

The electronic component 21 has a first surface 21a and a second surface 21b opposite to the first surface 21a, and a plurality of first conductive vias 210 penetrating through the first surface 21a and the second surface 21b are formed in the electronic component 21, such that the electronic component 21 is accommodated in the groove 200 of the circuit board 20 and is electrically connected to the circuit board 20.

The semiconductor component 22 is disposed on the first side 20a of the circuit board 20 and the first surface 21a of the electronic component 21 concurrently, such that the semiconductor component 22 is electrically connected to the circuit board 20 and the electronic component 21, and the semiconductor component 22 can be electrically connected to the circuit board 20 directly through the plurality of first conductive vias 210 of the electronic component 21

Moreover, the semiconductor component 22 has a third surface 22a and a fourth surface 22b opposite to the third surface 22a, and a plurality of second conductive vias 220 penetrating through the third surface 22a and the fourth surface 22b are formed in the semiconductor component 22.

The optical component 23 is disposed on the semiconductor component 22. The optical component 23 can be directly electrically connected to the semiconductor component 22, the electronic component 21, and the circuit board 20 through the plurality of first conductive vias 210 and the plurality of second conductive vias 220.

To sum up, in the optical package structure and the manufacturing method thereof of the present disclosure, the electronic component formed with a plurality of first conductive vias is accommodated in the groove of the circuit board so that the overall size of the optical package structure is reduced. Then, the semiconductor component is stacked on the electronic component, and the optical component is stacked on the semiconductor component, thereby constituting the three-layer vertically stacked optical package structure. At the same time, the optical component, the semiconductor component, the electronic component, and the circuit board can be electrically connected to each other directly through the plurality of first conductive vias formed in the electronic component and the plurality of second conductive vias formed in the semiconductor component. As a result, the signal transmission paths between the optical component, the semiconductor component, the electronic component, and the circuit board are reduced, thereby improving the transmission speed. Furthermore, the optical accessory can be supported by the circuit board to reduce the risk of breakage of the optical component. In addition, the implementation feasibility of the technology of the optical package structure is high, and the optical package structure can be manufactured using existing semiconductor packaging processes. There is no need to develop specialized processes or purchase special equipment, which can help reduce product production costs.

The above embodiments are for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An optical package structure, comprising:
a circuit board having a first side, a second side opposite to the first side, and a groove formed on the first side;
an electronic component having a first surface, a second surface opposite to the first surface, and a plurality of first conductive vias penetrating through the first surface and the second surface, wherein the electronic component is accommodated in the groove via the second surface and is electrically connected to the circuit board;
a semiconductor component having a third surface and a fourth surface opposite to the third surface, wherein the semiconductor component is disposed on the electronic component via the fourth surface and is electrically connected to the electronic component; and
an optical component disposed on and electrically connected to the semiconductor component.

2. The optical package structure of claim 1, wherein the electronic component is a switched application-specific integrated circuit.

3. The optical package structure of claim 1, wherein the semiconductor component is an electronic integrated circuit component.

4. The optical package structure of claim 1, wherein the semiconductor component is formed with a plurality of second conductive vias penetrating through the third surface and the fourth surface.

5. The optical package structure of claim 1, wherein the semiconductor component is disposed on the circuit board and the electronic component via the fourth surface and is electrically connected to the circuit board and the electronic component.

6. The optical package structure of claim 1, wherein the optical component is an optical chip or an optical module.

7. The optical package structure of claim 6, wherein the optical module comprises a coupler, an optical chip, a total reflection mirror, and an optical fiber array unit.

8. The optical package structure of claim 1, wherein the optical component is provided with an optical accessory, and the optical accessory is supported by the circuit board.

9. The optical package structure of claim 1, further comprising: a filling layer formed between the optical component and the circuit board and covering the semiconductor component and the electronic component.

10. The optical package structure of claim 1, further comprising: a plurality of conductive components placed on the second side of the circuit board.

11. The optical package structure of claim 1, wherein the circuit board, the electronic component disposed in the groove of the circuit board, the semiconductor component, and the optical component constitute a three-layer vertical stacked structure.

12. A method of manufacturing an optical package structure, comprising:
providing a circuit board having a first side, a second side opposite to the first side, and a groove formed on the first side;
disposing an electronic component in the groove of the circuit board, wherein the electronic component has a first surface, a second surface opposite to the first surface, and a plurality of first conductive vias penetrating through the first surface and the second surface, wherein the electronic component is accommodated in the groove via the second surface and is electrically connected to the circuit board;
disposing a semiconductor component on the electronic component, wherein the semiconductor component has a third surface and a fourth surface opposite to the third surface, wherein the semiconductor component is disposed on the electronic component via the fourth surface and is electrically connected to the electronic component; and
disposing an optical component on the semiconductor component, wherein the optical component is electrically connected to the semiconductor component.

13. The method of claim 12, wherein the electronic component is a switched application-specific integrated circuit.

14. The method of claim 12, wherein the semiconductor component is an electronic integrated circuit component.

15. The method of claim 12, wherein the semiconductor component is formed with a plurality of second conductive vias penetrating through the third surface and the fourth surface.

16. The method of claim 12, wherein the semiconductor component is disposed on the circuit board and the electronic component via the fourth surface and is electrically connected to the circuit board and the electronic component.

17. The method of claim 12, wherein the optical component is an optical chip or an optical module.

18. The method of claim 17, wherein the optical module comprises a coupler, an optical chip, a total reflection mirror, and an optical fiber array unit.

19. The method of claim 12, wherein the optical component is provided with an optical accessory, and the optical accessory is supported by the circuit board.

20. The method of claim 12, further comprising: forming a filling layer between the optical component and the circuit board to cover the semiconductor component and the electronic component.

21. The method of claim 12, further comprising: placing a plurality of conductive components on the second side of the circuit board.

22. The method of claim 12, wherein the circuit board, the electronic component disposed in the groove of the circuit board, the semiconductor component, and the optical component constitute a three-layer vertical stacked structure.
